(19) United States
(12) Patent Application Publication
(10) Pub. No.: US 2025/0125156 A1
(43) Pub. Date: Apr. 17, 2025

(54) METHOD FOR MANUFACTURING SEMICONDUCTOR DEVICE

(71) Applicant: SAMSUNG ELECTRONICS CO., LTD., Suwon-si (KR)

(72) Inventor: Hiroshi SASAKI, Suwon-si (JP)

(73) Assignee: SAMSUNG ELECTRONICS CO., LTD., Suwon-si (KR)

(21) Appl. No.: 18/629,411

(22) Filed: Apr. 8, 2024

(30) Foreign Application Priority Data
Oct. 11, 2023 (KR) 10-2023-0134961

(51) Int. Cl. H01L 21/311; H01L 21/02; H01L 21/28

(52) U.S. Cl. CPC H01L 21/31144; H01L 21/02118; H01L 21/28

(57) ABSTRACT

A method for manufacturing a semiconductor device is provided and includes: forming a stack structure on a substrate; forming a mask pattern on the stack structure; forming a trench inside the stack structure by performing an etching process, using a process gas, that etches a portion of the stack structure; and forming a protective film pattern on a sidewall and an upper surface of the mask pattern, wherein the process gas includes at least one from among MoF₆, MoF₄, AlF₃ and MgF₂, the protective film pattern includes a material different from a material of each of the mask pattern and the process gas, and a thickness of a portion of the protective film pattern formed on the upper surface of the mask pattern is greater than a thickness of a portion of the protective film pattern formed on the sidewall of the mask pattern.

### CROSS-REFERENCE TO RELATED APPLICATION

This application claims priority from Korean Patent Application No. 10-2023-0134961 filed on Oct. 11, 2023 in the Korean Intellectual Property Office, and all the benefits accruing therefrom under 35 U.S.C. 119, the contents of which in its entirety are herein incorporated by reference.

### BACKGROUND

### 1. Technical Field

Embodiments of the present disclosure relate to a method for manufacturing a semiconductor device.

### 2. Description of Related Art

Recently, as a structure of a semiconductor device has become highly integrated, a space for forming a hole or a trench extending in a vertical direction is becoming narrower. For this reason, research is underway to secure a process margin for forming the hole or the trench. Furthermore, as a depth of the hole or the trench extending in the vertical direction increases, a problem arises in which the trench is be formed so as to be bent during a process of forming the trench. For this reason, research is being conducted to prevent bending from occurring in the hole or the trench during the process of forming the hole or the trench.

### SUMMARY

According to embodiments of the present disclosure, a method is provided for manufacturing a semiconductor device capable of securing a process margin for forming a trench, and preventing bending from occurring at a lower portion of the trench.

According to embodiments of the present disclosure, a method for manufacturing a semiconductor device is provided and includes: forming a stack structure on a substrate; forming a first mask pattern on the stack structure; forming a first trench inside the stack structure by performing a first etching process, using a first process gas, that etches a portion of the stack structure; and forming a first protective film pattern on a sidewall and an upper surface of the first mask pattern, the first protective film pattern being present while the first etching process is performed, wherein the first process gas includes at least one from among MoF₆, MoF₄, AlF₃ and MgF₂, wherein the first protective film pattern includes a material different from a material of each of the first mask pattern and the first process gas, and wherein a thickness of a first portion of the first protective film pattern formed on the upper surface of the first mask pattern is greater than a thickness of a second portion of the first protective film pattern formed on the sidewall of the first mask pattern.

According to embodiments of the present disclosure, a method for manufacturing a semiconductor device is provided and includes: forming a stack structure on a substrate, the stack structure including first layers and second layers alternately stacked on top of each other, the first layers including oxide and the second layers including nitride; forming a first mask pattern on the stack structure; forming a first trench inside the stack structure by performing a first etching process, using a first process gas, that etches a portion of the stack structure; and forming a first protective film pattern on a sidewall and an upper surface of the first mask pattern, the first protective film pattern being present while the first etching process is performed, wherein the first process gas includes at least one from among MoF₆, MoF₄, AlF_{3,} and MgF₂, and wherein the first protective film pattern includes at least one from among an Mo polymer, an Al polymer, and an Mg polymer.

According to embodiments of the present disclosure, a method for manufacturing a semiconductor device is provided and includes: forming a stack structure on a substrate, the stack structure including first layers and second layers alternately stacked on top of each other, the first layers including oxide and the second layers including nitride; forming a mask pattern on the stack structure; forming a trench inside the stack structure by performing an etching process, using a process gas, that etches a portion of the stack structure, the trench exposing a portion of an upper surface of the substrate; and forming a protective film pattern on a sidewall and an upper surface of the mask pattern, the protective film pattern being present while the etching process is performed, wherein the process gas includes at least one from among MoF₆, MoF₄, AlF_{3,} and MgF₂, wherein the protective film pattern includes a material different from a material of the mask pattern, wherein the protective film pattern includes at least one from among an Mo polymer, an Al polymer, and an Mg polymer, and wherein a thickness of a first portion of the protective film pattern formed on the upper surface of the mask pattern is greater than a thickness of a second portion of the protective film pattern formed on the sidewall of the mask pattern.

Aspects of embodiments of the present disclosure are not limited to the above-mentioned aspects. Other aspects and advantages of embodiments of the present disclosure that are not mentioned may be understood based on following descriptions, and may be more clearly understood based on embodiments of the present disclosure. Further, it will be easily understood that aspects and advantages of embodiments of the present disclosure may be realized using means described in the claims and combinations thereof.

### BRIEF DESCRIPTION OF DRAWINGS

The above and other aspects and features of embodiments of the present disclosure will become more apparent by describing in detail non-limiting example embodiments with reference to the attached drawings, in which:

FIG. 1 is a flowchart for illustrating a method for manufacturing a semiconductor device according to some embodiments of the present disclosure.

FIGS. 2 to 4 are diagrams of intermediate structures corresponding to intermediate steps of a method for manufacturing a semiconductor device according to some embodiments of the present disclosure;

FIG. 5 is a diagram of an intermediate structure corresponding to an intermediate step of a method for manufacturing a semiconductor device according to some embodiments of the present disclosure;

FIG. 6 is a flowchart for illustrating a method for manufacturing a semiconductor device according to some embodiments of the present disclosure;

FIGS. 7 to 12 are diagrams of intermediate structures corresponding to intermediate steps of a method for manufacturing a semiconductor device according to some embodiments of the present disclosure;

FIG. 13 is a flowchart for illustrating a method for manufacturing a semiconductor device according to some embodiments of the present disclosure;

FIGS. 14 to 16 are diagrams of intermediate structures corresponding to intermediate steps of a method for manufacturing a semiconductor device according to some embodiments of the present disclosure; and

FIGS. 17 to 19 are diagrams of intermediate structures corresponding to intermediate steps of a method for manufacturing a semiconductor device according to some embodiments of the present disclosure.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

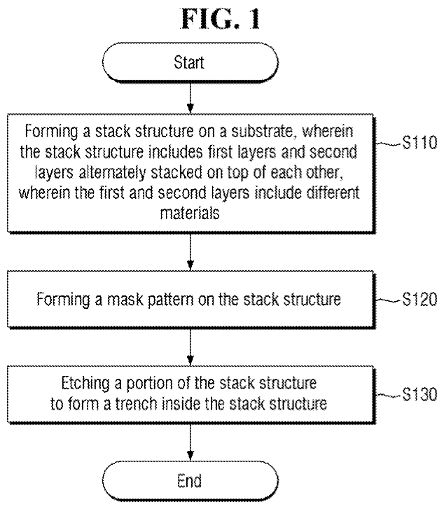

Hereinafter, a method for manufacturing a semiconductor device according to some embodiments of the present disclosure is described with reference to FIGS. 1 to 4. For example, the method for manufacturing the semiconductor device as shown in FIGS. 1 to 4 may be a partial process of a method for manufacturing a semiconductor device with a vertical NAND structure.

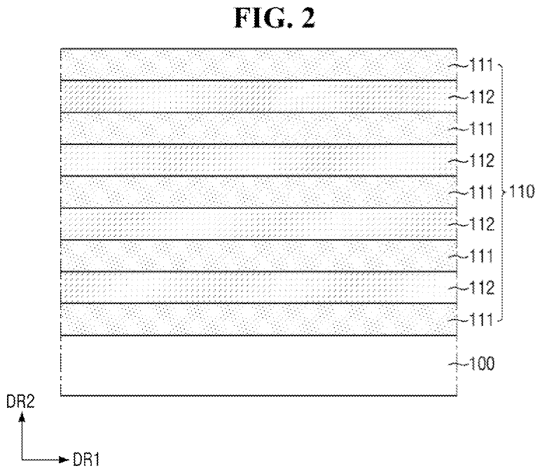

FIG. 1 is a flowchart for illustrating a method for manufacturing a semiconductor device according to some embodiments of the present disclosure. FIGS. 2 to 4 are diagrams of intermediate structures corresponding to intermediate steps of a method for manufacturing a semiconductor device according to some embodiments of the present disclosure.

Referring to FIG. 1 and FIG. 2, on a substrate 100, a stack structure 110 may be formed in which first layers 111 and second layers 112 including different materials are alternately stacked on top of each other in operation S110. For example, the substrate 100 may be made of bulk silicon or silicon-on-insulator (SOI). Alternatively, the substrate 100 may be a silicon substrate, or be made of a material other than silicon, such as silicon germanium, silicon germanium on insulator (SGOI), indium antimonide, lead telluride compound, indium arsenide, indium phosphide, gallium arsenide, or gallium antimonide. However, the present disclosure is not limited thereto.

Hereinafter, a horizontal direction DR1 may be defined as a direction parallel to an upper surface of the substrate 100. A vertical direction DR2 may be defined as a direction perpendicular to the horizontal direction DR1. That is, the vertical direction DR2 may be defined as a direction perpendicular to the upper surface of the substrate 100.

For example, the stack structure 110 may be formed on the upper surface of the substrate 100. The stack structure 110 may include the first layers 111 and the second layers 112 alternately stacked on top of each other while being disposed on the upper surface of the substrate 100. For example, one of the first layers 111 may be a lowermost layer of the stack structure 110 and another of the first layers 111 may be an uppermost layer of the stack structure 110. That is, one of the first layers 111 may be in contact with the upper surface of the substrate 100. However, embodiments of the present disclosure are not limited thereto. In some embodiments, one of the second layers 112 may be the uppermost layer of the stack structure 110.

For example, the first layers 111 and the second layers 112 may include different materials from each other. For example, the first layers 111 may include oxide, and the second layers 112 may include nitride. For example, the first layers 111 may include silicon oxide (SiO₂), and the second layers 112 may include silicon nitride (SiN).

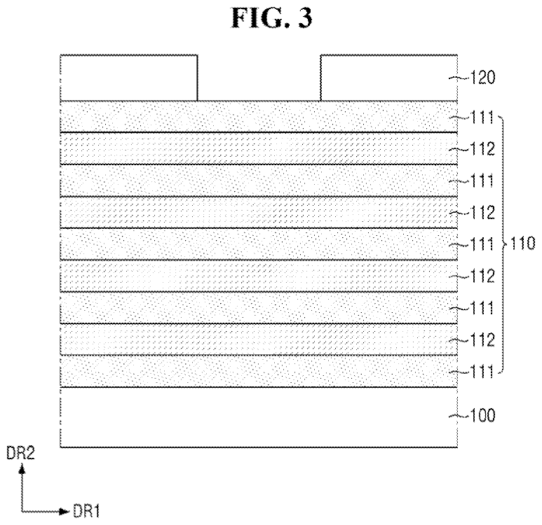

Referring to FIG. 1 and FIG. 3, a first mask pattern 120 may be formed on the stack structure 110 in operation S120.

For example, the first mask pattern 120 may be formed on an upper surface of the stack structure 110. That is, the first mask pattern 120 may be formed on an upper surface of an uppermost one of the first layers 111. The first mask pattern 120 may not cover at least a portion of the upper surface of the stack structure 110 such that at least the portion of the upper surface is exposed.

That is, the first mask pattern 120 may not cover at least a portion of the upper surface of the uppermost one of the first layers 111 such that at least the portion of the upper surface is exposed. For example, the first mask pattern 120 may include a material having an etch selectivity with respect to a material of each of the first layers 111 and the second layers 112.

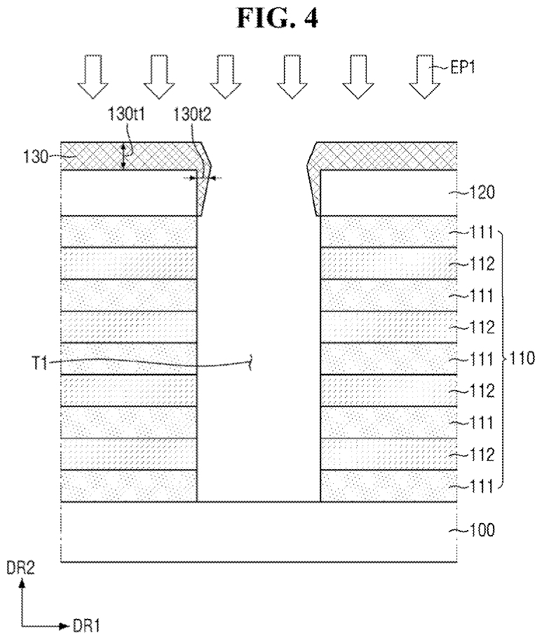

Referring to FIG. 1 and FIG. 4, a first trench T1 may be formed inside the stack structure 110 by etching the stack structure 110 in operation S130.

For example, a first etching process EP1 may be performed using a first process gas such that a portion of the stack structure 110 is etched to form the first trench T1 inside the stack structure 110. For example, the first trench T1 may extend through the stack structure 110 in the vertical direction DR2 to the upper surface of the substrate 100. For example, the first trench T1 may expose a portion of the upper surface of the substrate 100.

For example, the first process gas may include one of MoF₆, MoF₄, AlF₃, and MgF₂. However, embodiments of the present disclosure are not limited thereto. In some embodiments, the first process gas may include one of CoF₂, CoF₃, TiCl₄, RuF₃, RuF₅, TaF₅, PtF₄, and PtF₆.

For example, while the first etching process EP1 is performed, a first protective film pattern 130 may be formed on a sidewall and an upper surface of the first mask pattern 120. For example, a thickness 130t1 in the vertical direction DR2 of the first protective film pattern 130 formed on the upper surface of the first mask pattern 120 may be greater than a thickness 130t2 in the horizontal direction DR1 of the first protective film pattern 130.

For example, the first protective film pattern 130 may include a material different from a material of the first mask pattern 120. Furthermore, the first protective film pattern 130 may include a material different than a material of the first process gas. The first protective film pattern 130 may include a metal polymer. For example, the first protective film pattern 130 may include one of Mo polymer, Al polymer, and Mg polymer. For example, the first protective film pattern 130 may include a metal polymer containing the same metal element as a metal element contained in the first process gas.

For example, in forming a trench by performing an etching process using a process gas containing WF₆, it may be relatively difficult to secure a process margin for forming the trench, and bending phenomenon in which a lower portion of the trench is bent may occur. In contrast, the method for manufacturing the semiconductor device according to some embodiments of the present disclosure may perform the first etching process EP1 using the first process gas including one of MoF₆, MoF₄, AlF₃, and MgF₂ to form the first trench T1.

For example, it may be easier to secure the process margin when the first process gas used to form the first trench T1 includes AlF₃ or MgF₂ than when using WF₆ as the process gas. Furthermore, for example, when the first process gas used to form the first trench T1 includes MoF₆ or MoF₄, the bending phenomenon in which a lower portion of the trench is bent may be prevented, whereas when WF₆ is used as the process gas, the bending phenomenon may occur.

That is, the method for manufacturing the semiconductor device according to some embodiments of the present disclosure may secure the process margin for forming the trench and prevent the bending of the lower portion of the trench, by forming the first trench T1 using the first process gas including one of MoF₆, MoF₄, AlF₃, and MgF₂.

Furthermore, in the method for manufacturing a semiconductor device according to some embodiments of the present disclosure, while forming the first trench T1 using the first process gas including one of MoF₆, MoF₄, AlF₃, and MgF₂, the first protective film pattern 130 containing the metal polymer containing the same metal element as the metal element contained in the first process gas may be formed on the sidewall and the upper surface of the first mask pattern 120. Furthermore, the thickness 130t1 in the vertical direction DR2 of a portion of the first protective film pattern 130 formed on the upper surface of the first mask pattern 120 may be greater than the thickness 130t2 in the horizontal direction DR1 of a portion of the first protective film pattern 130 formed on the sidewall of the first mask pattern 120.

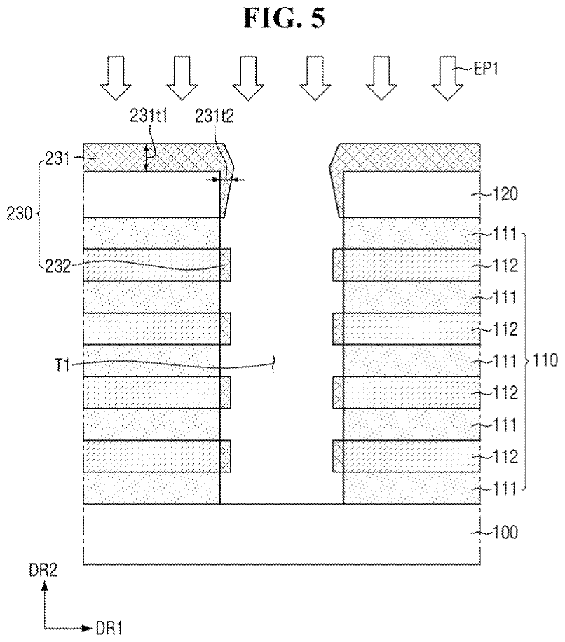

Hereinafter, with reference to FIG. 5, a method for manufacturing a semiconductor device according to some embodiments of the present disclosure is described. The following descriptions are mainly based on differences thereof from the method for manufacturing the semiconductor device as shown in FIGS. 1 to 4. For example, the method for manufacturing the semiconductor device as shown in FIG. 5 may be a partial process of the method for manufacturing a semiconductor device with a vertical NAND structure.

FIG. 5 is a diagram of an intermediate structure corresponding to an intermediate step of a method for manufacturing a semiconductor device according to some embodiments of the present disclosure.

Referring to FIG. 5, in the method for manufacturing the semiconductor device according to some embodiments of the present disclosure, after the process as shown in FIG. 2 and FIG. 3 has been performed, the first etching process EP1 using the first process gas may be performed such that a portion of the stack structure 110 is etched to form the first trench T1 inside the stack structure 110.

For example, while the first etching process EP1 is performed, the first protective film pattern 230 may be formed on the sidewall and the upper surface of the first mask pattern 120. For example, the first protective film pattern 230 may include a first portion 231 and a second portion 232. The first portion 231 of the first protective film pattern 230 may be formed on the sidewall and the upper surface of the first mask pattern 120. The second portion 232 of the first protective film pattern 230 may be formed on a sidewall of each of the second layers 112 exposed by the first trench T1.

For example, a thickness 231t1 in the vertical direction DR2 of a portion of the first portion 231 of the first protective film pattern 230 formed on the upper surface of the first mask pattern 120 may be greater than a thickness 231t2 in the horizontal direction DR1 of a portion of the first portion 231 of the first protective film pattern 230 formed on the sidewall of the first mask pattern 120.

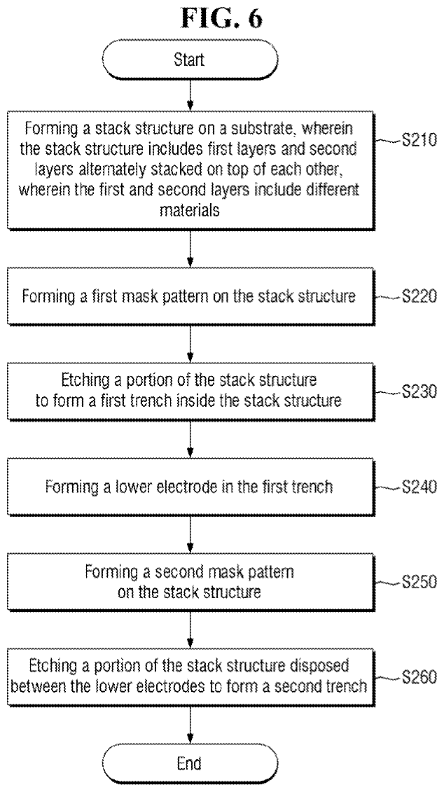

Hereinafter, with reference to FIGS. 6 to 12, a method for manufacturing a semiconductor device according to some embodiments of the present disclosure is described. For example, the method for manufacturing the semiconductor device as shown in FIGS. 6 to 12 may be a partial process of the method for manufacturing a semiconductor device having a DRAM structure.

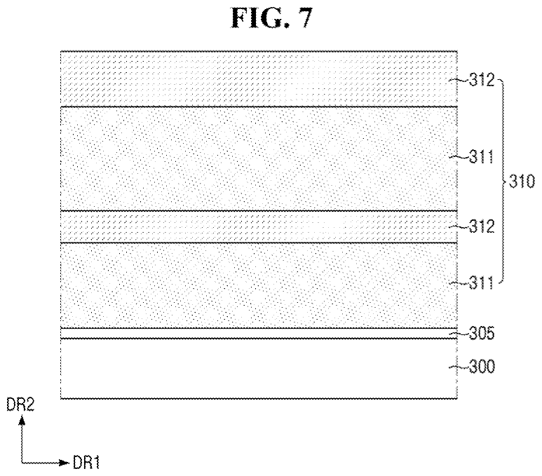

Referring to FIG. 6 and FIG. 7, on a substrate 300, a stack structure 310 may be formed in which first layers 311 and second layers 312 including different materials are alternately stacked on top of each other in operation S210.

For example, the substrate 300 may be made of bulk silicon or silicon-on-insulator (SOI). Alternatively, the substrate 300 may be a silicon substrate, or may be made of a material other than silicon, such as silicon germanium, silicon germanium on insulator (SGOI), indium antimonide, lead telluride compound, indium arsenide, indium phosphide, gallium arsenide, or gallium antimonide. However, embodiments of the present disclosure are not limited thereto.

According to some embodiments, a gate electrode used as a word line and an interlayer insulating film surrounding the gate electrode may be formed inside the substrate 300. For example, the gate electrode may include a conductive material. For example, the interlayer insulating film may include a low dielectric constant material. A unit active region and an element isolation region may be formed in the substrate 300. For example, two transistors may be formed in one unit active region.

For example, an etching stop film 305 may be formed on an upper surface of the substrate 300. For example, the etching stop film 305 may be made of at least one from among silicon nitride (SiN), silicon carbonitride (SiCN), silicon boronitride (SiBN), silicon carbonate (SiCO), silicon oxynitride (SiON), silicon oxide (SiO₂) and silicon oxycarbonitride (SiOCN).

Subsequently, the stack structure 310 may be formed on an upper surface of the etching stop film 305. The stack structure 310 may include the first layers 311 and the second layers 312 alternately stacked on top of each other while being disposed on the upper surface of the etching stop film 305. For example, one of the first layers 311 may be the lowest layer of the stack structure 310. That is, the one of the first layers 311 may be in contact with the upper surface of the etching stop film 305. For example, one of the second layers 312 may be the uppermost layer of the stack structure 310. For example, a thickness in the vertical direction DR2 of the one of the second layers 312 as the uppermost layer of the stack structure 310 may be greater than a thickness in the vertical direction DR2 of the second layers 312 disposed between the first layers 311 of the stack structure 310.

For example, the first layers 311 and the second layers 312 may include different materials from each other. For example, the first layers 311 may include oxide. The second layers 312 may include nitride. For example, the first layers 311 may include silicon oxide (SiO₂). The second layers 312 may include at least one from among silicon nitride (SiN), silicon carbonitride (SiCN), silicon boronitride (SiBN), silicon carbonate (SiCO), silicon oxynitride (SiON), and silicon oxycarbonitride (SiOCN).

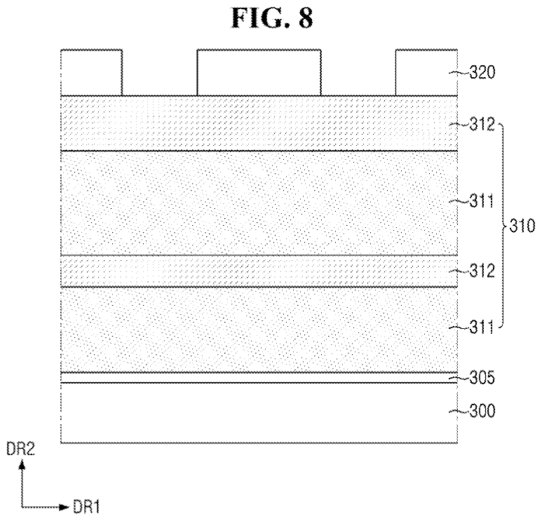

Referring to FIG. 6 and FIG. 8, a first mask pattern 320 may be formed on the stack structure 310 in S220.

For example, the first mask pattern 320 may be formed on an upper surface of the stack structure 310. That is, the first mask pattern 320 may be formed on an upper surface of the uppermost one of the second layers 312. The first mask pattern 320 may not cover at least a portion of the upper surface of the stack structure 310 such that the at least the portion of the upper surface is exposed. That is, the first mask pattern 320 may not cover at least a portion of the upper surface of the uppermost one of the second layers 312 such that at least the portion of the upper surface is exposed. For example, the first mask pattern 320 may include a material having an etch selectivity with respect to a material of each of the first layers 311 and the second layers 312.

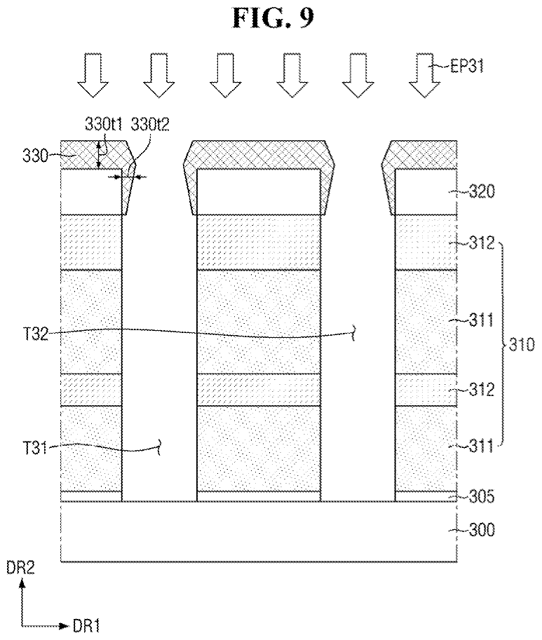

Referring to FIG. 6 and FIG. 9, a first trench T31 and a second trench T32 may be formed inside the stack structure 310 by etching a portion of the stack structure 310 in operation S230.

For example, a first etching process EP31 may be performed using the first process gas such that the portion of the stack structure 310 and a portion of the etching stop film 305 are etched to form a first trench T31 and a second trench T32. For example, the second trench T32 may be spaced apart from the first trench T31 in the horizontal direction DR1. For example, each of the first trench T31 and the second trench T32 may extend through the stack structure 310 and the etching stop film 305 in the vertical direction DR2 to the upper surface of the substrate 300. For example, each of the first trench T31 and the second trench T32 may expose a portion of the upper surface of the substrate 300 therethrough.

For example, the first process gas may include one of MoF₆, MoF₄, AlF₃, and MgF₂. However, embodiments of the present disclosure are not limited thereto. In some embodiments, the first process gas may include one of CoF₂, CoF₃, TiCl₄, RuF₃, RuF₅, TaF₅, PtF₄, and PtF₆.

For example, while the first etching process EP31 is performed, the first protective film pattern 330 may be formed on a sidewall and an upper surface of the first mask pattern 320. For example, a thickness 330t1 in the vertical direction DR2 of a portion of the first protective film pattern 330 formed on the upper surface of the first mask pattern 320 may be greater than a thickness 330t2 in the horizontal direction DR1 of a portion of the first protective film pattern 330 formed on the sidewall of the first mask pattern 320.

For example, the first protective film pattern 330 may include a different material from a material of the first mask pattern 320. Furthermore, the first protective film pattern 330 may include a material that is different from a material of the first process gas. The first protective film pattern 330 may include a metal polymer. For example, the first protective film pattern 330 may include one of Mo polymer, Al polymer, and Mg polymer. For example, the first protective film pattern 330 may include a metal polymer containing the same metal element as a metal element contained in the first process gas.

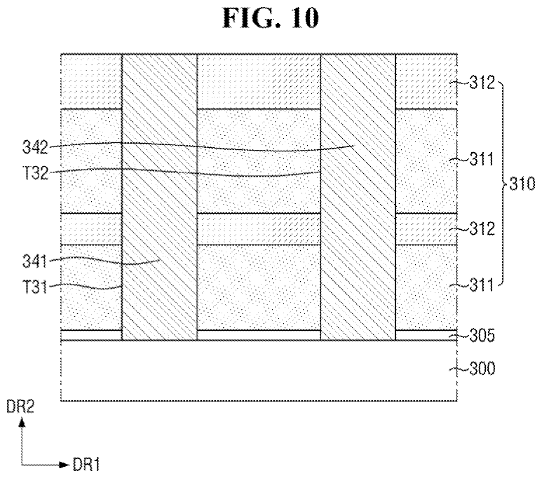

Referring to FIG. 6 and FIG. 10, the first protective film pattern 330 (refer to FIG. 9) and the first mask pattern 320 (refer to FIG. 9) may be removed. Subsequently, a first lower electrode 341 may be formed inside the first trench T31, and a second lower electrode 342 may be formed inside the second trench T32 in operation S240.

For example, the second lower electrode 342 may be spaced apart from the first lower electrode 341 in the horizontal direction DR1. For example, a lower surface of each of the first lower electrode 341 and the second lower electrode 342 may be in contact with the upper surface of the substrate 300. For example, an upper surface of each of the first lower electrode 341 and the second lower electrode 342 may be coplanar with an upper surface of the uppermost one of the second layers 312 of the stack structure 310.

Each of the first lower electrode 341 and the second lower electrode 342 may include a conductive material. For example, each of the first lower electrode 341 and the second lower electrode 342 may include a conductive metal nitride (e.g., titanium nitride, tantalum nitride, niobium nitride, or tungsten nitride, etc.), a metal (e.g., ruthenium, iridium, titanium, or tantalum, etc.), a conductive metal oxide (e.g., iridium oxide, niobium oxide, etc.), etc. However, embodiments of the present disclosure are not limited thereto.

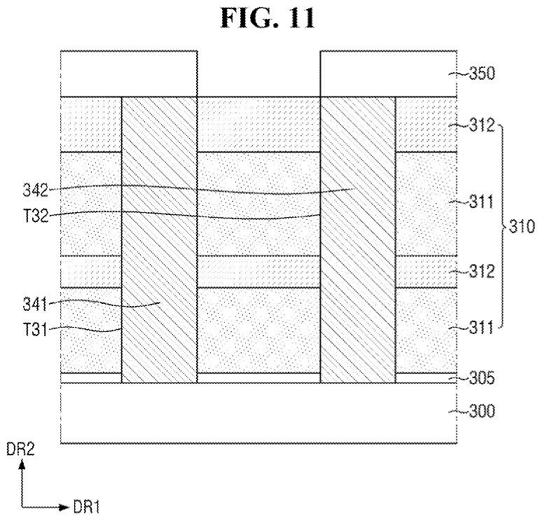

Referring to FIG. 6 and FIG. 11, the second mask pattern 350 may be formed on the stack structure 310, the first lower electrode 341, and the second lower electrode 342 in operation S250.

For example, a second mask pattern 350 may be formed on the upper surface of each of the stack structure 310, the first lower electrode 341, and the second lower electrode 342. That is, the second mask pattern 350 may be formed on the upper surface of each of the uppermost one of the second layers 312, the first lower electrode 341, and the second lower electrode 342. The second mask pattern 350 may not cover the upper surface of a portion of the stack structure 310 disposed between the first lower electrode 341 and the second lower electrode 342 such that the upper surface of the portion is exposed. That is, the second mask pattern 350 may not cover an upper surface of a portion of the uppermost one of the second layers 312 disposed between the first lower electrode 341 and the second lower electrode 342 such that the upper surface of the portion is exposed. For example, the second mask pattern 350 may include a material having an etch selectivity with respect to a material of each of the first layers 311, the second layers 312, the first lower electrode 341, and the second lower electrode 342.

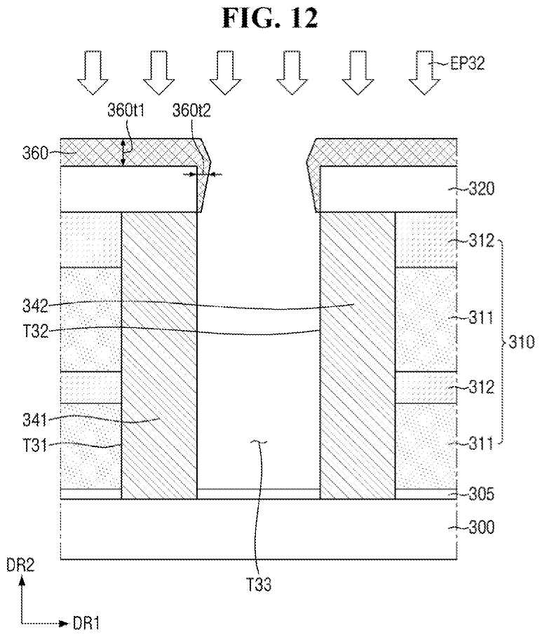

Referring to FIG. 6 and FIG. 12, a third trench T33 may be formed inside the stack structure 310 by etching a portion of the stack structure 310 in operation S260.

For example, a second etching process EP32 may be performed using a second process gas such that the portion of the stack structure 310 may be etched to form the third trench T33 inside the stack structure 310. For example, the third trench T33 may be formed between the first lower electrode 341 and the second lower electrode 342 and on the etching stop film 305. The third trench T33 may expose a sidewall of each of the first lower electrode 341 and the second lower electrode 342 therethrough. For example, the third trench T33 may extend through the stack structure 310 in the vertical direction DR2 to the upper surface of the etching stop film 305. For example, the third trench T33 may expose a portion of the upper surface of the etching stop film 305 therethrough.

For example, the second process gas may include one of MoF₆, MoF₄, AlF₃, and MgF₂. However, embodiments of the present disclosure are not limited thereto. In some embodiments, the second process gas may include one of CoF₂, CoF₃, TiCl₄, RuF₃, RuF₅, TaF₅, PtF₄, and PtF₆.

For example, while the second etching process EP32 is performed, a second protective film pattern 360 may be formed on a sidewall and an upper surface of the second mask pattern 350. For example, a thickness 360t1 in the vertical direction DR2 of a portion of the second protective film pattern 360 formed on the upper surface of the second mask pattern 350 may be greater than a thickness 360t2 in the horizontal direction DR1 of a portion of the second protective film pattern 360 formed on the sidewall of the second mask pattern 350.

For example, the second protective film pattern 360 may include a different material from a material of the second mask pattern 350. Furthermore, the second protective film pattern 360 may include a material different than a material of the second process gas. The second protective film pattern 360 may include a metal polymer. For example, the second protective film pattern 360 may include one of Mo polymer, Al polymer, and Mg polymer. For example, the second protective film pattern 360 may include a metal polymer containing the same metal element as a metal element contained in the second process gas.

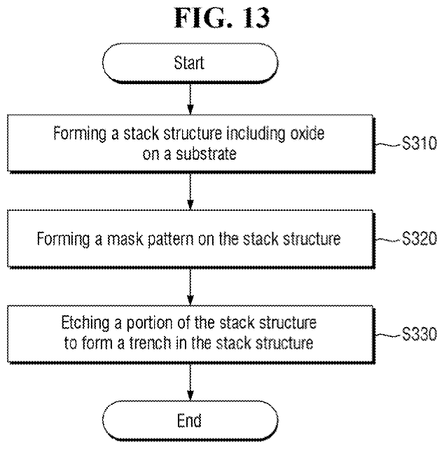

Hereinafter, with reference to FIGS. 13 to 16, a method for manufacturing a semiconductor device according to some embodiments of the present disclosure is described. For example, the method for manufacturing the semiconductor device as shown in FIGS. 13 to 16 may be a partial process of a method for manufacturing a semiconductor device in which a contact or a via is formed.

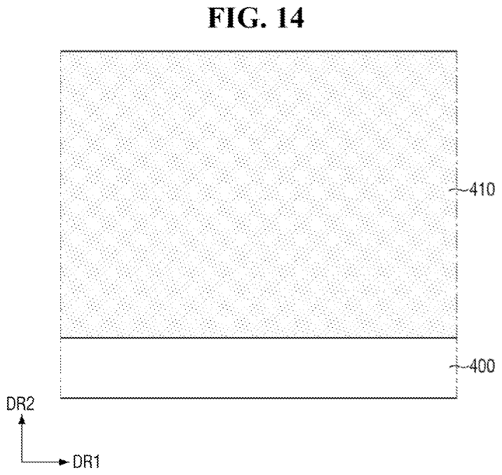

FIG. 13 is a flowchart for illustrating a method for manufacturing a semiconductor device according to some embodiments of the present disclosure. FIGS. 14 to 16 are diagrams of intermediate structures corresponding to intermediate steps of a method for manufacturing a semiconductor device according to some embodiments of the present disclosure.

Referring to FIG. 13 and FIG. 14, a stack structure 410 including oxide may be formed on a substrate 400 in operation S310.

For example, the substrate 400 may be made of bulk silicon or silicon-on-insulator (SOI). Alternatively, the substrate 400 may be a silicon substrate, or may be made of a material other than silicon, such as silicon germanium, silicon germanium on insulator (SGOI), indium antimonide, lead telluride compound, indium arsenide, indium phosphide, gallium arsenide, or gallium antimonide. However, embodiments of the present disclosure are not limited thereto.

According to some embodiments, a gate electrode including a conductive material, source/drain regions, and an interlayer insulating film surrounding the gate electrode and the source/drain regions may be formed inside the substrate 400. For example, the gate electrode may include a conductive material. For example, the interlayer insulating film may include a low dielectric constant material.

For example, the stack structure 410 may be formed on an upper surface of the substrate 400. For example, the stack structure 410 may be formed as a single film. The stack structure 410 may include a low dielectric constant material. For example, the stack structure 410 may include silicon oxide (SiO₂).

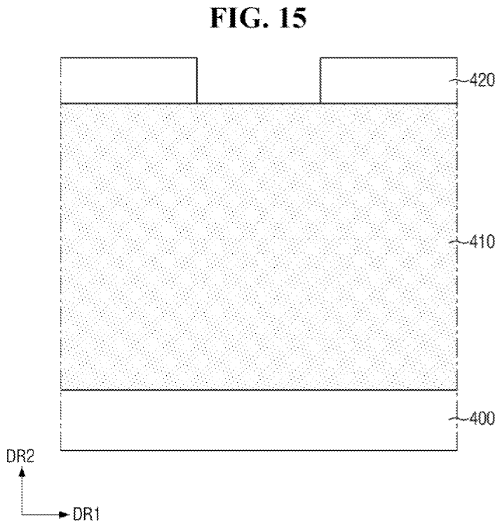

Referring to FIG. 13 and FIG. 15, a first mask pattern 420 may be formed on the stack structure 410 in operation S320.

For example, the first mask pattern 420 may be formed on an upper surface of the stack structure 410. The first mask pattern 420 may not cover at least a portion of the upper surface of the stack structure 410 such that the portion of the upper surface is exposed. For example, the first mask pattern 420 may include a material having an etch selectivity with respect to a material of the stack structure 410.

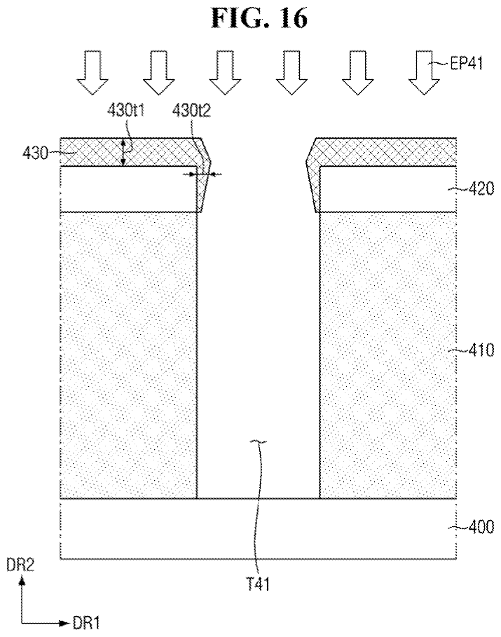

Referring to FIG. 13 and FIG. 16, a first trench T41 may be formed inside the stack structure 410 by etching a portion of the stack structure 410 in operation S330.

For example, a first etching process EP41 may be performed using the first process gas such that the portion of the stack structure 410 is etched to form the first trench T41 inside the stack structure 410. For example, the first trench T41 may extend through the stack structure 410 in the vertical direction DR2 to the upper surface of the substrate 400. For example, the first trench T41 may expose the upper surface of the substrate 400 therethrough.

For example, the first process gas may include one of MoF₆, MoF₄, AlF₃, and MgF₂. However, embodiments of the present disclosure are not limited thereto. In some embodiments, the first process gas may include one of CoF₂, CoF₃, TiCl₄, RuF₃, RuF₅, TaF₅, PtF₄, and PtF₆.

For example, while the first etching process EP41 is performed, a first protective film pattern 430 may be formed on a sidewall and an upper surface of the first mask pattern 420. For example, a thickness 430t1 in the vertical direction DR2 of a portion of the first protective film pattern 430 formed on the upper surface of the first mask pattern 420 may be greater than a thickness 430t2 in the horizontal direction DR1 of a portion of the first protective film pattern 430 formed on the sidewall of the first mask pattern 420.

For example, the first protective film pattern 430 may include a different material from a material of the first mask pattern 420. Furthermore, the first protective film pattern 430 may include a material that is different from a material of the first process gas. The first protective film pattern 430 may include a metal polymer. For example, the first protective film pattern 430 may include one of Mo polymer, Al polymer, and Mg polymer. For example, the first protective film pattern 430 may include a metal polymer containing the same metal element as a metal element contained in the first process gas.

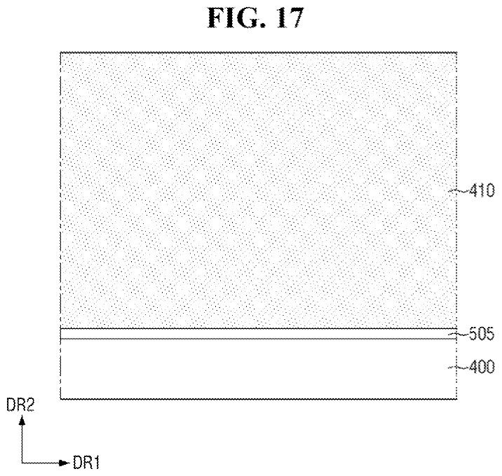

Hereinafter, with reference to FIGS. 17 to 19, a method for manufacturing a semiconductor device according to some embodiments of the present disclosure is described. The following descriptions are mainly based on differences thereof from the method for manufacturing the semiconductor device as shown in FIG. 13 to FIG. 16. For example, the method for manufacturing the semiconductor device as shown in FIGS. 17 to 19 may be a partial process of a method for manufacturing a semiconductor device in which a contact or a via is formed.

FIGS. 17 to 19 are drawings of intermediate steps corresponding to intermediate structures for describing a method for manufacturing a semiconductor device according to some embodiments of the present disclosure.

Referring to FIG. 17, in a method for manufacturing a semiconductor device according to some embodiments of the present disclosure, an etching stop film 505 may be formed on the upper surface of the substrate 400. For example, the etching stop film 505 may include at least one from among silicon nitride (SiN), silicon carbonitride (SiCN), silicon boronitride (SiBN), silicon carbonate (SiCO), silicon oxynitride (SiON), silicon oxide (SiO₂) and silicon oxycarbonitride (SiOCN). Subsequently, the stack structure 410 may be formed on an upper surface of the etching stop film 505.

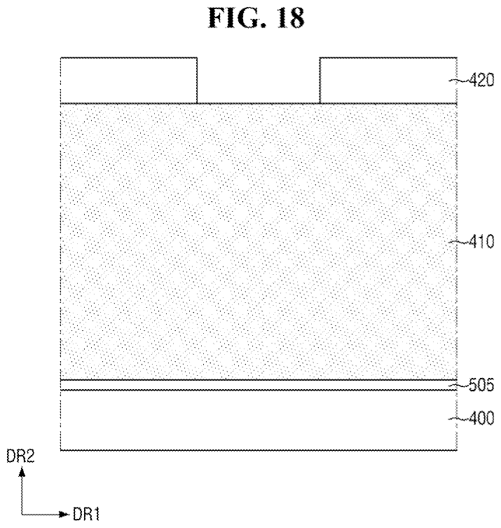

Referring to FIG. 18, the first mask pattern 420 may be formed on the upper surface of the stack structure 410. The first mask pattern 420 may not cover at least a portion of the upper surface of the stack structure 410 such that the at least the portion of the upper surface is exposed. For example, the first mask pattern 420 may include a material having an etch selectivity with respect to a material of the stack structure 410.

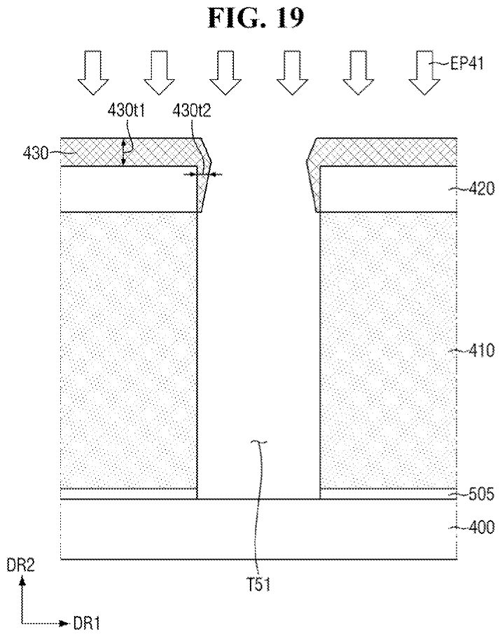

Referring to FIG. 19, the first etching process EP41 may be performed using the first process gas such that a portion of the stack structure 410 and a portion of the etching stop film 505 are etched to form a first trench T51 the inside the stack structure 410. For example, the first trench T51 may extend through the stack structure 410 and the etching stop film 505 in the vertical direction DR2 to the upper surface of the substrate 400. For example, the first trench T51 may expose a portion of the upper surface of the substrate 400 therethrough.

Although non-limiting example embodiments of the present disclosure have been described with reference to the accompanying drawings, embodiments of the present disclosure are not limited to the example embodiments, and may be implemented in various different forms. A person skilled in the art may appreciate that embodiments of the present disclosure may be practiced in other concrete forms without departing from the technical spirit of the present disclosure. Therefore, it should be appreciated that the embodiments as described above are examples, and are not restrictive in any respect.

What is claimed is:

1. A method for manufacturing a semiconductor device, the method comprising:
forming a stack structure on a substrate;
forming a first mask pattern on the stack structure;
forming a first trench inside the stack structure by performing a first etching process, using a first process gas, that etches a portion of the stack structure; and
forming a first protective film pattern on a sidewall and an upper surface of the first mask pattern, the first protective film pattern being present while the first etching process is performed,
wherein the first process gas includes at least one from among MoF₆, MoF₄, AlF₃ and MgF₂,
wherein the first protective film pattern includes a material different from a material of each of the first mask pattern and the first process gas, and
wherein a thickness of a first portion of the first protective film pattern formed on the upper surface of the first mask pattern is greater than a thickness of a second portion of the first protective film pattern formed on the sidewall of the first mask pattern.

2. The method of claim 1, wherein the first protective film pattern includes at least one from among Mo polymer, Al polymer, and Mg polymer.

3. The method of claim 1, wherein the stack structure includes first layers and second layers disposed on the substrate and alternately stacked on top of each other, the first layers and the second layers including different materials from each other.

4. The method of claim 3, wherein the first layers include oxide, and the second layers include nitride.

5. The method of claim 1, wherein the first trench exposes a portion of an upper surface of the substrate.

6. The method of claim 1, wherein the forming the stack structure on the substrate comprises:
forming an etching stop film on the substrate; and
forming the stack structure on the etching stop film.

7. The method of claim 6, wherein the forming the first trench inside the stack structure comprises etching the portion of the stack structure and a portion of the etching stop film so as to expose a portion of an upper surface of the substrate.

8. The method of claim 6, wherein the forming the first trench inside the stack structure comprises etching the portion of the stack structure so as to expose a portion of an upper surface of the etching stop film.

9. The method of claim 1, further comprising:
removing, after the forming the first trench, the first mask pattern and the first protective film pattern; and
forming a lower electrode in the first trench.

10. The method of claim 9, further comprising:
forming, after forming the lower electrode, a second mask pattern on the stack structure and the lower electrode;
form a second trench exposing a sidewall of the lower electrode by performing a second etching process, using a second process gas, that etches another portion of the stack structure; and
forming a second protective film pattern on a sidewall and an upper surface of the second mask pattern, the second protective film pattern being present while the second etching process is performed,
wherein the second process gas includes at least one from among MoF₆, MoF₄, AlF₃, and MgF₂.

11. The method of claim 10, wherein the second protective film pattern includes a material different from a material of each of the second mask pattern and the second process gas, and
wherein a thickness of a portion of the second protective film pattern formed on the upper surface of the second mask pattern is greater than a thickness of a portion of the first protective film pattern formed on the sidewall of the second mask pattern.

12. The method of claim 1, wherein the stack structure is a single film including oxide.

13. A method for manufacturing a semiconductor device, the method comprising:
forming a stack structure on a substrate, the stack structure including first layers and second layers alternately stacked on top of each other, the first layers including oxide and the second layers including nitride;
forming a first mask pattern on the stack structure;
forming a first trench inside the stack structure by performing a first etching process, using a first process gas, that etches a portion of the stack structure; and
forming a first protective film pattern on a sidewall and an upper surface of the first mask pattern, the first protective film pattern being present while the first etching process is performed,
wherein the first process gas includes at least one from among MoF₆, MoF₄, AlF₃, and MgF₂, and
wherein the first protective film pattern includes at least one from among an Mo polymer, an Al polymer, and an Mg polymer.

14. The method of claim 13, wherein the first protective film pattern includes a material different from a material of the first mask pattern.

15. The method of claim 13, wherein a thickness of a first portion of the first protective film pattern formed on the upper surface of the first mask pattern is greater than a thickness of a second portion of the first protective film pattern formed on the sidewall of the first mask pattern.

16. The method of claim 13, wherein the first trench exposes a portion of an upper surface of the substrate.

17. The method of claim 13, wherein the first protective film pattern includes:
a first portion formed on the sidewall and the upper surface of the first mask pattern; and
a second portion formed on a sidewall of each of the second layers exposed by the first trench.

18. The method of claim 13, further comprising:
removing, after the forming the first trench, the first mask pattern and the first protective film pattern; and
forming a lower electrode in the first trench.

19. The method of claim 18, further comprising:
forming, after the forming the lower electrode, a second mask pattern on the stack structure and the lower electrode;
forming a second trench exposing a sidewall of the lower electrode by performing a second etching process, using a second process gas, that etches another portion of the stack structure; and
forming a second protective film pattern on a sidewall and an upper surface of the second mask pattern, the second protective film pattern being present while the second etching process is performed,
wherein the second process gas includes at least from among MoF₆, MoF₄, AlF₃ and MgF₂.

20. A method for manufacturing a semiconductor device, the method comprising:
forming a stack structure on a substrate, the stack structure including first layers and second layers alternately stacked on top of each other, the first layers including oxide and the second layers including nitride;
forming a mask pattern on the stack structure;
forming a trench inside the stack structure by performing an etching process, using a process gas, that etches a portion of the stack structure, the trench exposing a portion of an upper surface of the substrate; and
forming a protective film pattern on a sidewall and an upper surface of the mask pattern, the protective film pattern being present while the etching process is performed, wherein the process gas includes at least one from among MoF₆, MoF₄, AlF_{3,} and MgF₂,
wherein the protective film pattern includes a material different from a material of the mask pattern,
wherein the protective film pattern includes at least one from among an Mo polymer, an Al polymer, and an Mg polymer, and
wherein a thickness of a first portion of the protective film pattern formed on the upper surface of the mask pattern is greater than a thickness of a second portion of the protective film pattern formed on the sidewall of the mask pattern.
